(19) United States
(12) Patent Application Publication
(10) Pub. No.: US 2008/0265268 A1
(43) Pub. Date: Oct. 30, 2008

(54) Optoelectronic Component

(75) Inventors: Bert Braune, Wenzenbach (DE); Herbert Brunner, Sinzing (DE); Kirstin Petersen, Freiburg (DE); Jorg Strauss, Regensburg (DE)

Correspondence Address: FISH & RICHARDSON PC, P.O. BOX 1022, MINNEAPOLIS, MN, 55440-1022, US

(73) Assignee: OSRAM OPTO SEMICONDUCTORS GMBH, Regensburg (DE)

(21) Appl. No.: 12/064,939

(22) PCT Filed: Aug. 24, 2006
(86) PCT No.: PCT/DE2006/001493

§ 371 Date: Jul. 9, 2008

(30) Foreign Application Priority Data
Aug. 30, 2005 (DE) 10 2005 041 063.4
May 3, 2006 (DE) 10 2006 020 529.4

(51) Int. Cl. H01L 33/00

(52) U.S. Cl. 257/98; 257/E33.055

(57) ABSTRACT

An optoelectronic component is described, comprising a semiconductor body that emits electromagnetic radiation of a first wavelength when the optoelectronic component is in operation, and a separate optical element disposed spacedly downstream of the semiconductor body in its radiation direction. The optical element comprises at least one first wavelength conversion material that converts radiation of the first wavelength to radiation of a second wavelength different from the first.

### CROSS-REFERENCE TO RELATED APPLICATIONS

This application is the National Stage of International Application No PCT/DE2006/001493, filed Aug. 24, 2006, which claims priority to German Patent Application No. 10 2005 041 063.4., filed Aug. 30, 2005, and German Patent Application No. 10 2006 020 529.4, filed May 3, 2006, the contents of which are incorporated herein by reference.

### FIELD OF INVENTION

This disclosure relates to an optoelectronic component comprising wavelength conversion materials.

### BACKGROUND OF THE INVENTION

Radiation-emitting optoelectronic components comprising wavelength conversion materials are described, for example, in the document WO 97/50132. Such an optoelectronic component includes a semiconductor body that emits electromagnetic radiation when operating, and wavelength conversion materials that are incorporated into an encapsulant of the semiconductor body or are disposed in a layer on the semiconductor body. The wavelength conversion materials convert a portion of the electromagnetic radiation emitted by the semiconductor body to radiation of another, usually higher, wavelength, such that the component emits mixed radiation.

As described for example in the document DE 102 61 428, it is also possible to dispose multiple layers comprising different wavelength conversion materials downstream of the radiation-emitting semiconductor body, such that different fractions of the radiation emitted by the radiation-emitting body are converted by different wavelength conversion materials to radiation in different regions of the spectrum.

In the past, attempts have been made to improve the efficiency of optoelectronic components comprising wavelength conversion materials by increasing the efficiency of the semiconductor body and the wavelength conversion material, on the one hand, and on the other hand by improving the geometry of the component housing to this effect.

### SUMMARY OF THE INVENTION

One object of the present invention is to specify an optoelectronic component comprising wavelength conversion materials and exhibiting high efficiency. Another object of the present invention is to specify an optoelectronic component comprising a wavelength conversion material and exhibiting high efficiency in conjunction with good color rendering. These objects are achieved by means of an optoelectronic component having the features of claim 1. Advantageous improvements and embodiments of the optoelectronic component are set forth in Dependent claims 2 to 25.

An optoelectronic component having high efficiency includes, in particular:
a semiconductor body that emits electromagnetic radiation of a first wavelength when the optoelectronic component is in operation, and
a separate optical element disposed spacedly downstream of the semiconductor body in its radiation direction, said optical element comprising at least one first wavelength conversion material that converts radiation of the first wavelength to radiation of a second wavelength different from the first wavelength.

“Spacedly,” in the present context, means in particular that the optical element is arranged such that it is spatially separated from the semiconductor body in a prescribed manner, a defined gap that is free of wavelength conversion material being formed between the semiconductor body and the optical element.

Since the first wavelength conversion material is comprised by the optical element, which is disposed spacedly from the radiation-emitting semiconductor body, the first wavelength conversion material is also disposed spacedly from the radiation-generating semiconductor body. The efficiency of the component is advantageously increased over that of an optoelectronic component in which the first wavelength conversion material is disposed directly adjacent the radiation-emitting semiconductor body and in particular directly adjacent its radiation-emitting front side, for example within an encapsulant of the semiconductor body or of a layer. In addition, it is particularly advantageous to incorporate the wavelength conversion material into the optical element, which serves to effect beam shaping and essentially determines the radiation characteristic of the component, since, as a rule, the radiation characteristic obtained in this way is not only enhanced, but is also particularly uniform.

In a particularly preferred embodiment, the wavelength conversion material includes particles and the optical element comprises a matrix material in which the particles are embedded. Since the radiation emitted by the semiconductor body and the radiation converted by the wavelength conversion material are normally scattered by the particles, and since the wavelength conversion material emits radiation in random directions, a wavelength conversion material comprising particles will, as a rule, advantageously increase the uniformity of the radiation characteristic of the component. Furthermore, disposing the particles of the first wavelength conversion material spacedly from the semiconductor body, in a separate optical element of defined geometry, yields the advantage that less radiation, particularly converted radiation, is deflected back into the semiconductor body by scattering from the particles, and is absorbed there, than is the case if the wavelength conversion material is contained in a wavelength conversion element that is directly adjacent the semiconductor body, such as a layer or an encapsulant, for example.

In a preferred embodiment, the first wavelength is in the ultraviolet, blue and/or green region of the spectrum. Since wavelength conversion materials normally convert radiation to radiation of higher wavelengths, wavelengths from the short-wave end of the visible spectrum and the ultraviolet region of the spectrum are particularly suitable for use in combination with wavelength conversion materials.

A semiconductor body that emits ultraviolet, blue and/or green radiation preferably comprises an active layer sequence that is suitable for emitting electromagnetic radiation in the particular spectral region and is made of a nitride- or phosphide-based compound semiconductor material.

“Nitride-based compound semiconductor material” means in the present context that the active layer sequence or at least a portion thereof comprises a nitride III compound semiconductor material, preferably AlₙGaₘIn₁₋ₙ₋ₘN, where 0≦n≦1, 0≦m≦1 and n+m≦1. The composition of this material need not necessarily be mathematically exactly that of the above formula. Rather, it can contain one or more dopants and additional constituents that do not substantially alter the characteristic physical properties of the AlₙGaₘIn₁₋ₙ₋ₘN material. For the sake of simplicity, however, the above formula includes only the essential components of the crystal lattice (Al, Ga, In, N), even though these may be partially replaced by very small quantities of other substances. By the same token, “phosphide-based compound semiconductor material” means in the present context that the active layer sequence or at least a portion thereof comprises a phosphide III compound semiconductor material, preferably AlₙGaₘIn₁₋ₙ₋ₘP, where 0≦n≦1, 0≦m≦1 and n+m≦1. The composition of this material need not necessarily be mathematically exactly that of the above formula. Rather, it can contain one or more dopants and additional constituents that do not substantially alter the characteristic physical properties of the AlₙGaₘIn₁₋ₙ₋ₘP material. For the sake of simplicity, however, the above formula includes only the essential components of the crystal lattice (Al, Ga, In, P), even though these may be partially replaced by very small quantities of other substances.

The active layer sequence of the semiconductor body is, for example, epitaxially grown and preferably has a pn junction, a double heterostructure, a single quantum well or, particularly preferably, a multiple quantum well (MQW) structure. The term “quantum well structure” carries no implication here as to the dimensionality of the quantization. It therefore includes, among other things, quantum troughs, quantum wires and quantum dots and any combination of these structures.

The semiconductor body can be, for example, a light-emitting diode chip (“LED chip” for short) or a thin-film light-emitting diode chip (“thin-film LED chip” for short). However, other radiation-generating semiconductor bodies, such as laser diodes, are also suitable for use in the component.

A thin-film LED chip is distinguished in particular by at least one of the following characteristic features:
applied to or formed on a first main surface of a radiation-generating epitaxial layer sequence, which surface faces a carrier element, is a reflective layer that reflects at least some of the electromagnetic radiation generated in the epitaxial layer sequence back into the latter,
the epitaxial layer sequence has a thickness in the region of 20 μm or less, particularly preferably in the region of 10 μm or less.

Furthermore, the epitaxial layer sequence preferably includes at least one semiconductor layer that has at least one surface with an intermixed structure that in the ideal case brings about a nearly ergodic distribution of the light in the epitaxial layer sequence, i.e., said layer has a stochastic scattering behavior that is as ergodic as possible.

A basic principle of a thin-layer LED chip is described, for example, in I. Schnitzer et al., Appl. Phys. Lett. 63 (16), Oct. 18, 1993, 2174-2176, whose disclosure content in that regard is hereby incorporated by reference.

A thin-film LED chip is, as a good approximation, a Lambertian surface radiator, and is therefore particularly suitable for use in an optical system, such as a floodlight, for example.

If the first wavelength is in the visible region of the spectrum, then the component preferably emits polychromatic mixed radiation that includes radiation of the first wavelength and radiation of the second wavelength. The term “polychromatic mixed radiation” here denotes in particular mixed radiation that includes radiation of different colors. Particularly preferably, the color space of the mixed radiation is in the white region of the CIE standard chromaticity diagram. It is therefore possible, via the choice and concentration of the wavelength conversion material, to fabricate components whose color space can be adjusted over wide ranges.

Particularly preferably, a semiconductor body that emits radiation in the blue region of the spectrum is used in combination with a wavelength conversion material that converts this blue radiation to yellow radiation. An optoelectronic component is thereby obtained that emits mixed radiation having a color space in the white region of the CIE standard chromaticity diagram.

If the semiconductor body emits only non-visible radiation, however, for example in the UV region, then efforts are made to convert this radiation as fully as possible, since it does not contribute to the brightness of the component. In the case of short-wave radiation, such as UV radiation, it may even damage the human eye. For this reason, with components of this kind, measures are preferably taken to prevent the component from emitting short-wave radiation.

Such measures can be, for example, absorber particles or reflective elements, which are disposed downstream of the first wavelength conversion material in the radiation direction of the semiconductor body and absorb the unwanted short-wave radiation or reflect it back to the wavelength conversion material.

It should be pointed out at this juncture that, as explained in still further detail below, a component can also emit polychromatic mixed radiation in cases where the semiconductor body emits only non-visible radiation. This is brought about by using at least two different wavelength conversion materials that convert the incident radiation to different wavelengths. If the semiconductor body emits only non-visible radiation, then this embodiment is particularly advantageous in comparison to converting the non-visible radiation to only one second wavelength. If the component comprises more than one wavelength conversion material, then measures to prevent the component from emitting short-wave radiation are preferably disposed downstream of all the wavelength conversion materials in the radiation direction of the semiconductor body.

In a preferred embodiment of the optoelectronic component, the semiconductor body is provided with an encapsulant that is transparent to the radiation emitted by the component. The semiconductor body can in this case be disposed in a recess in a component housing, such as a reflector trough, for example. Alternatively, the semiconductor body can also be mounted on a circuit board or on a cooling element of a circuit board. One function performed by the encapsulant is to protect the semiconductor body. In addition, the encapsulant is preferably so arranged that it fills the gap between the optical element and the semiconductor body and thereby decreases the refractive index mismatch on the path of the radiation from the semiconductor body to the optical element, thus advantageously reducing radiation losses due to reflection at interfaces.

The encapsulant preferably contains a matrix material comprising a silicone material, an epoxy material, a hybrid material or a refractive-index-matched material. The term “refractive-index-matched material” is understood to be a material whose refractive index falls between the refractive indices of the adjacent materials, hence, in the present context, between the refractive index of the semiconductor body and the refractive index of the matrix material of the optical element.

In a further preferred embodiment of the optoelectronic component, the encapsulant comprises at least one second wavelength conversion material different from the first. The second wavelength conversion material preferably converts the radiation from the first wavelength conversion material to radiation of a third wavelength different from the first and second wavelengths, such that the component emits mixed radiation of the second wavelength, the third wavelength and, where appropriate, the first wavelength.

The mutually spatially separated arrangement of the first wavelength conversion material and the second wavelength conversion material achieves the effect, in particular, of reducing the absorption by one of the wavelength conversion materials of radiation that has already been converted by the respective other wavelength conversion material. This is a risk, in particular, when the one wavelength conversion material converts the radiation to a wavelength that is close to the excitation wavelength of the other wavelength conversion material. The described arrangement and spatial separation of the two wavelength conversion materials increases the efficiency of the component, as well as the uniformity of the color impression and the reproducibility of these parameters during mass production.

A semiconductor body that emits only non-visible radiation in the ultraviolet region is also particularly suitable for this embodiment of the optoelectronic component. In this case, a portion of the radiation emitted by the semiconductor body is preferably converted to radiation of the third wavelength by the second wavelength conversion material in the encapsulant. Another portion, and any remaining portion of the radiation emitted by the semiconductor body that similarly passes unconverted through the encapsulant, are converted to radiation of the second wavelength by the first wavelength conversion material in the optical element, such that the component emits polychromatic mixed radiation composed of radiation of the second and the third wavelength.

In this exemplary embodiment, as well, the second wavelength conversion material preferably includes particles that are embedded in the matrix material of the encapsulant.

Furthermore, in this exemplary embodiment the semiconductor body and the two wavelength conversion materials are preferably adapted to each other in such a way that the radiation of the first wavelength comes from the blue region of the spectrum, and the second wavelength conversion material converts a portion of this blue radiation to red radiation and the first wavelength conversion material converts another portion of the remaining blue radiation to green radiation, such that the component emits white mixed radiation having red, green and blue components. The color space of the white mixed radiation can be matched to a desired value especially well in this case by adjusting the quantities of wavelength conversion materials.

In another preferred embodiment, disposed between the encapsulant and the optical element is a coupling layer comprising a refractive-index-matched material whose refractive index falls between the refractive index of the encapsulant and the refractive index of the matrix material of the optical element, thereby reducing radiation losses caused by reflections at the interfaces. Furthermore, the coupling layer can also serve to mechanically connect the encapsulant and the optical element.

Additionally or alternatively to the second wavelength conversion material in the encapsulant, a wavelength conversion layer comprising at least one wavelength conversion material that is different from the first and, where applicable, from the second wavelength conversion material can also be applied to the semiconductor body. This third wavelength conversion material preferably converts the radiation of the first wavelength to radiation of a fourth wavelength, such that the component emits mixed radiation of the third, of the fourth, where applicable of the second, and where applicable of the first wavelength.

If the wavelength conversion material disposed on the semiconductor body is used alternatively to the second wavelength conversion material disposed in the encapsulant, here again, the semiconductor body and the two wavelength conversion materials are adapted to one another in such a way that the radiation from the first wavelength conversion material is in the blue region of the spectrum, the third wavelength conversion material converts a portion of this radiation to red radiation, and the first wavelength conversion material converts a further portion of the residual radiation to green radiation, such that the component emits white mixed radiation having red, green and blue components.

As described above, the wavelength conversion layer need not necessarily be disposed on the semiconductor body. On the contrary, a wavelength conversion layer can also be disposed between the encapsulant and the optical element. Furthermore, it is possible for the component to have not just one, but a plurality of wavelength conversion layers, each preferably comprising different wavelength conversion materials.

If the wavelength conversion layer is used in addition to the second wavelength conversion material in the encapsulant, such that a total of at least three different wavelength conversion materials are used in the component, then a semiconductor body emitting non-visible radiation in the ultraviolet region of the spectrum is preferably used. A portion of the non-visible radiation from the semiconductor body is then converted to radiation in the red region of the spectrum, preferably by the third wavelength conversion material of the wavelength conversion layer, whereas another portion of the non-visible radiation emitted by the semiconductor body passes unconverted through the wavelength conversion layer, and another portion of this unconverted radiation is converted to radiation in the green region of the spectrum by the second wavelength conversion material in the encapsulant. A further portion of the non-visible radiation passes in turn unconverted through the encapsulant. The last portion of the non-visible radiation having passed unconverted through the encapsulant is then converted, preferably completely, to blue radiation, so that the component emits mixed radiation in the red, green and blue regions of the spectrum having a color space in the white region of the CIE standard chromaticity diagram. Depending on the desired color space of the mixed radiation, it is also conceivable for radiation from the semiconductor body to be converted to other respective regions of the spectrum.

The use of at least three wavelength conversion materials in combination with a semiconductor body emitting radiation in the visible region of the spectrum can be effective, for example, when the mixed radiation emitted by the component is intended to conform to a given color space.

In one preferred embodiment, the thickness of the wavelength conversion layer is constant, since the path length of the radiation within the wavelength conversion layer then becomes uniform. This advantageously imparts uniformity to the color impression given by the optoelectronic component.

If the component includes a wavelength conversion layer comprising a third wavelength conversion material, then the wavelength conversion layer preferably in turn comprises a matrix material and the third wavelength conversion material includes particles that are embedded in the matrix material.

As a rule, the matrix material of the wavelength conversion layer comprises or consists of a polymer that hardens to transparency, such as, for example, an epoxy, an acrylate, a polyester, a polyimide or a polyurethane, or a chlorine-containing polymer, such as, for example, a polyvinyl chloride. Mixtures of the above-cited materials are also suitable for use as the matrix material, as are silicones and hybrid materials, which are usually mixed forms composed of silicones, epoxies and acrylates. Polymers that contain polysiloxane chains are generally suitable as the matrix material.

When more than one spatially separated wavelength conversion material is used, said materials are preferably so arranged that the wavelength to which the radiation of the first wavelength is converted by the particular wavelength conversion material is in each case shorter, as viewed from the semiconductor body in its radiation direction, than the wavelength to which the preceding wavelength conversion material, with respect to the radiation direction of the semiconductor chip, converts the radiation of the first wavelength. This operates particularly effectively to prevent already converted radiation from being absorbed by a wavelength conversion material that is downstream in the radiation direction of the semiconductor chip.

The first, second and third wavelength conversion materials are selected, for example, from the group formed by the following materials: garnets doped with rare earth metals, alkaline earth sulfides doped with rare earth metals, thiogallates doped with rare earth metals, aluminates doped with rare earth metals, orthosilicates doped with rare earth metals, chlorosilicates doped with rare earth metals, alkaline earth silicon nitrides doped with rare earth metals, oxynitrides doped with rare earth metals, and aluminum oxynitrides doped with rare earth metals.

A Ce-doped YAG wavelength conversion material (YAG:Ce) is particularly preferably used as the first, second or third wavelength conversion material.

The optical element is preferably a lens, particularly preferably a convex lens. The optical element serves to shape the radiation characteristic of the optoelectronic component in a desired manner. Spherical lenses or aspherical lenses, for example elliptical lenses, can be used for this purpose. It is further conceivable to use other optical elements for beam shaping, such as, for example, a solid body configured in a pyramidal or truncated cone shape or in the manner of a compound parabolic concentrator, a compound elliptical concentrator or a compound hyperbolic concentrator.

The optical element comprises, as matrix material for the particles of the wavelength conversion material, for example a material selected from the group formed by the following materials: glass, polymethyl methacrylate (PMMA), polycarbonate (PC), cyclic olefins (COC), silicones and polymethyl methylacrylimide (PMMI).

Particularly preferably, the particular wavelength conversion material is distributed substantially uniformly in the matrix material of the optical element and/or in the matrix material of the encapsulant and/or in the matrix material of the wavelength conversion layer. A substantially uniform distribution of the wavelength conversion material advantageously leads, as a rule, to a very uniform radiation characteristic and a very uniform color impression from the optoelectronic component. The phrase “substantially uniform” means in the present context that the particles of the wavelength conversion material are distributed in the particular matrix material as evenly as is possible and useful within the limits of technical feasibility. It particularly means that the particles are not agglomerated.

However, the possibility is not to be ruled out that the arrangement of the particles in the matrix material may deviate slightly from an ideal uniform distribution, for example as a result of sedimentation of the particles during the hardening of the particular matrix material.

In a preferred embodiment, the matrix material of the optical element and/or the matrix material of the encapsulant and/or the matrix material of the wavelength conversion layer comprises light-scattering particles. These can advantageously impart uniformity to the radiation characteristic or influence the optical properties of the component in a desirable manner.

It should be noted at this point that, as a rule, the semiconductor body does not emit radiation of a single first wavelength, but rather, radiation of a plurality of different first wavelengths that preferably fall within a common first wavelength range. The first, second or third wavelength conversion material converts radiation at least from a single first wavelength to radiation of at least one other, second, third or fourth wavelength. As a rule, the first, second or third wavelength conversion material converts radiation of a plurality of first wavelengths that preferably fall within a first wavelength range to radiation of a plurality of other, second, third or fourth, wavelengths, which in turn fall within another common second, third or fourth wavelength range.

### DESCRIPTION OF THE DRAWINGS

The invention is explained in more detail below with reference to five exemplary embodiments, considered in conjunction with FIGS. 1A and 1B and 2 to 6.

Therein:

FIG. 1A is a schematic sectional representation of an optoelectronic component according to a first exemplary embodiment,

FIG. 1B is a schematic sectional representation through a component housing for the optoelectronic component according to FIG. 1A,

FIGS. 2 to 5 are schematic sectional representations of optoelectronic components according to four other exemplary embodiments, and

FIG. 6 is a schematic exploded representation of an optoelectronic component according to another exemplary embodiment.

### DETAILED DESCRIPTION OF THE PREFERRED EMBODIMENTS

In the exemplary embodiments and figures, like or like-acting elements are provided with the same respective reference numerals. The illustrated elements are basically not to be considered true to scale, but rather, individual elements, such as for example layer thicknesses, may be depicted as exaggeratedly large for the sake of better understanding.

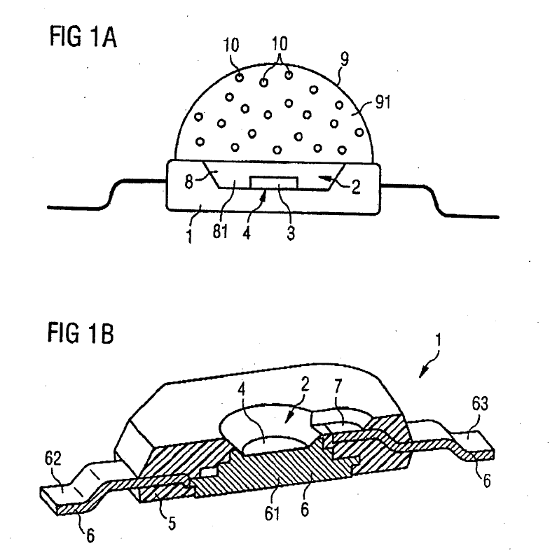

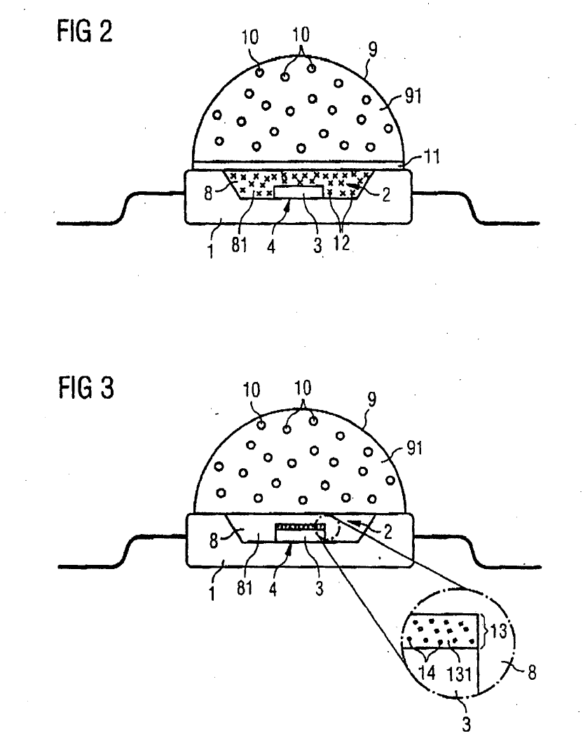

The optoelectronic component according to the exemplary embodiment of FIG. 1A includes a component housing 1 with a recess 2 in which an LED chip 3 is mounted on a chip mounting area 4. Herein, the “front side” of the LED chip and of the optoelectronic component will denote the radiation-emitting side in the particular case, and the “back side” will be the side opposite that front side.

As illustrated in FIG. 1B, the component housing 1 comprises a base body 5 and a leadframe 6. The leadframe 6 includes a thermal connector 61 and two wing-shaped electrical connectors 62, 63 that jut out laterally from the base body 5. The thermal connector 61, in addition, is also electrically conductive and forms the “floor” of the chip mounting area 4. The one electrical connector 62 is electrically conductively connected to the thermal connector 61, whereas the other electrical connector 63 is electrically conductively connected to a wire connection area 7 of the base body 5. The LED chip 3, when being mounted on the chip mounting area 4, is electrically conductively connected from the back to thermally conductive connector 61, and in a further mounting step is electrically contacted from the front to wire connection area 7 by means of a bonding wire (not shown). In the case of the component housing 1 of FIG. 1B, the recess 2 in which the LED chip 3 is mounted is configured as a reflector trough that serves to perform beam shaping.

A suitable component housing 1 is described in the document WO 02/084749 A2, whose disclosure content in that regard is hereby incorporated by reference.

The semiconductor chip in the case under consideration is a gallium nitride based LED chip 3 that emits electromagnetic radiation of a first wavelength, for instance in the blue region of the spectrum. The recess 2 in the component housing 1 in which the LED chip 3 is mounted is filled with an encapsulant 8, for example comprising a silicone compound as matrix material 81. Disposed downstream of the encapsulant 8 in the radiation direction of the LED chip 3 is a separately fabricated lens 9, which is mounted on the base body 5 of the component housing 1. In the present case, the lens 9 comprises polycarbonate as matrix material 91. However, silicones, PAAI or polyurethane (PU) are also suitable as the matrix material 91 of the lens 9. Furthermore, the lens 9 inwardly comprises particles of a first wavelength conversion material 10 that partially converts the radiation of the first wavelength from the LED chip 3, i.e., for example, in the blue region of the spectrum, to radiation of a second wavelength, for instance in the yellow region of the spectrum, such that the component as a whole emits white radiation from its front side. The particles of the first wavelength conversion material 10 in the case at hand are distributed substantially uniformly and without agglomeration in the matrix material of the lens 9. YAG:Ce, for example, can be used as the first wavelength conversion material 10.

In the case under consideration, the spaced-apart arrangement of the first wavelength conversion material 10 in the optical element 9 particularly also advantageously increases the backscattering of converted radiation from the particles of the first wavelength conversion material 10 to recess 2 configured as a reflector trough, thereby increasing the efficiency of the component.

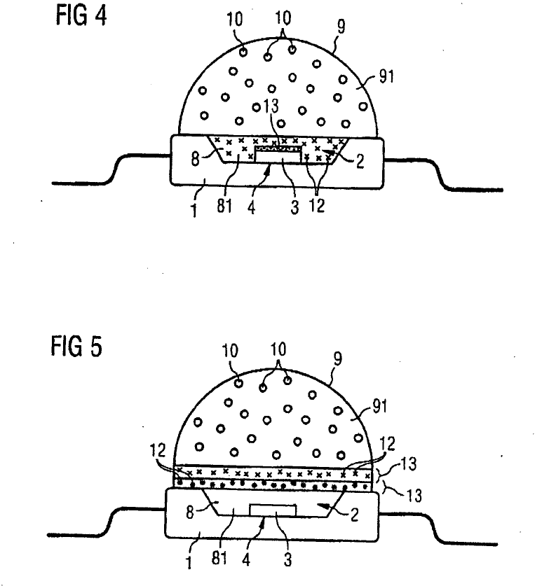

In the optoelectronic component according to the second exemplary embodiment, that of FIG. 2, in contrast to the optoelectronic component according to FIGS. 1A and 1B, a coupling layer 11 is disposed between the lens 9 and the encapsulant 8 or the base body 5 of the component housing 1. In addition, a second wavelength conversion material 12 is embedded in the matrix material 81 of the transparent encapsulant 8 of the LED chip 3 and fills the recess 2 in the base body 5. The coupling layer 11 comprises a silicone-based material and has a refractive index between 1.4 and 1.5. In addition to the function of reducing the refractive index mismatch between the matrix material 81 of the encapsulant 8 and the matrix material 91 of the lens 9, coupling layer 11 also has the function in this case of mechanically fixing the lens 9 to the encapsulant 8 or to the base body 5 of the component housing 1.

As distinguished from the first wavelength conversion material 10 in FIG. 1, the first wavelength conversion material 10 of FIG. 2 converts a portion of the blue radiation from the LED chip 3 to radiation of a second wavelength that is, for example, in the green region of the spectrum, whereas the second wavelength conversion material 12 converts a portion of the radiation from the LED chip 3 having a first wavelength in the blue region of the spectrum to radiation of a third wavelength, for example in the red region of the spectrum. The component according to FIG. 2 emits polychromatic mixed radiation that includes red radiation converted by second wavelength conversion material 12, green radiation converted by first wavelength conversion material 10 and unconverted blue radiation from the LED chip 3. The color space of this particular mixed radiation is in the white region of the CIE standard chromaticity diagram. The first wavelength conversion material 10, which is suitable for converting a portion of the blue radiation to radiation in the green region of the spectrum, can be, for example, a green-emitting Eu-doped nitride, while the second wavelength conversion material 12, which is suitable for converting a portion of the blue radiation to radiation in the red region of the spectrum, can be a red-emitting Eu-doped nitride.

Two wavelength conversion materials 10, 14 are also used in the optoelectronic component according to the exemplary embodiment of FIG. 3. As in the two previously described exemplary embodiments, the first wavelength conversion material 10 is disposed, substantially uniformly distributed, in the matrix material 91 of the lens 9. As in the second exemplary embodiment, the first wavelength conversion material 10 converts the radiation of the first wavelength from the LED chip 3, which is in the blue region of the spectrum, partially to radiation of a second wavelength, for example in the green region of the spectrum. In contrast to the exemplary embodiment according to FIG. 2, however, here there is no wavelength conversion material in the matrix material 81 of the encapsulant 8 of the LED chip 3. Instead, applied to the front side of the LED chip 3 is a wavelength conversion layer 13 comprising a matrix material 131 in which a third wavelength conversion material 14 is embedded. The third wavelength conversion material 14 converts another portion of the radiation of the first wavelength in the blue region of the spectrum that is emitted by the LED chip 3 to radiation of a fourth wavelength, for example in the red region of the spectrum.

The thickness of the wavelength conversion layer 13 comprising the third wavelength conversion material 14 is substantially constant in the present case, so the path length of the blue radiation in the wavelength conversion layer 13 is substantially constant and the fraction of the radiation converted by the third wavelength conversion material 14 does not depend on the position of the converting particles in the wavelength conversion layer 13. This contributes to a uniform color impression from the component. Like the component according to FIG. 2, the component according to FIG. 3 emits mixed radiation having blue, red and green spectral components, the color space of which is in the white region of the CIE standard chromaticity diagram.

In the optoelectronic component according to the exemplary embodiment of FIG. 4, in contrast to the above-cited exemplary embodiments, an LED chip 3 is used that emits radiation of a first wavelength in the ultraviolet region of the spectrum. Furthermore, three wavelength conversion materials 10, 12, 14 are used in this component, each of which converts a portion of this ultraviolet radiation to another region of the visible light spectrum. The first wavelength conversion material 10 is again distributed substantially uniformly in the matrix material 91 of the lens 9 and converts a portion of the ultraviolet radiation to radiation of a first wavelength in the visible blue spectral region. The second wavelength conversion material 12, which is contained, also substantially uniformly distributed, in the matrix material 81 of the encapsulant 8, converts another portion of the ultraviolet radiation from the LED chip 3 to radiation of a third wavelength, for example in the visible green spectral region. The remaining portion of the ultraviolet radiation emitted by the LED chip 3 is converted by a third wavelength conversion material 14, which is disposed in a wavelength conversion layer 13 on the LED chip 3, to radiation of a fourth wavelength in the visible red spectral region. As in the exemplary embodiments according to FIGS. 2 and 3, the component emits white mixed radiation having red, green and blue spectral components. In contrast to the exemplary embodiments of FIGS. 2 and 3, however, the radiation from the LED chip 3 is ideally converted completely into visible light by the wavelength conversion materials 10, 12, 14.

The first wavelength conversion material 10, which is suitable for converting a portion of the ultraviolet radiation to radiation in the blue region of the spectrum, can be, for example, a barium magnesium aluminate, while the second wavelength conversion material 12, which is suitable for converting a portion of the ultraviolet radiation to radiation in the green region of the spectrum, can be a green-emitting Eu-doped nitride. The third wavelength conversion material 14, which is suitable for converting radiation in the ultraviolet region of the spectrum to radiation in the red region of the spectrum, can be, for example, a red-emitting Eu-doped nitride.

In the exemplary embodiment of FIG. 5, the component comprises, in addition to a first wavelength conversion material 10, which is contained in the lens 9, two other wavelength conversion materials 12 (referred to hereinafter as second wavelength conversion materials), which are disposed in a first and a second wavelength conversion layer 13 between the encapsulant 8 of the LED chip 3 and the lens 9. The LED chip 3 in this exemplary embodiment is suitable for emitting radiation of a first wavelength in the blue region of the spectrum. The second wavelength conversion material 12 of the first wavelength conversion layer 13, which is disposed on the encapsulant 8 of the LED chip 3, converts radiation of the first wavelength in the blue spectral region generated by the LED chip 3 to radiation of a fourth wavelength in the red spectral region. A portion of the blue radiation emitted by the LED chip 3 passes unconverted through first wavelength conversion layer 13 and impinges on second wavelength conversion layer 13, which is disposed on first wavelength conversion layer 13. Second wavelength conversion layer 13 comprises another second wavelength conversion material 12, which is suitable for converting another portion of the radiation of the first wavelength emitted by the LED chip 3 to radiation of another second wavelength in the yellow region of the spectrum. Another portion of the blue radiation emitted by the LED chip 3 also passes through second wavelength conversion layer 13 unconverted and is converted by first wavelength conversion material 10 in the optical element 9 to radiation of a second wavelength in the green region of the spectrum. A portion of the radiation of the first wavelength emitted by the LED chip 3 passes, in turn, unconverted through optical element 9. The component therefore emits mixed radiation that emanates radiation in the yellow, green, blue and red regions of the spectrum. The color space of the mixed-color radiation can be adjusted within the warm-white region of the CIE standard chromaticity diagram by mixing in radiation from the yellow region of the spectrum.

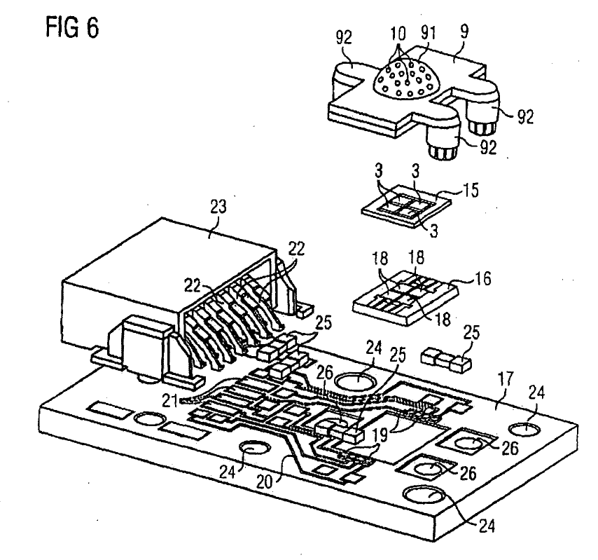

The component according to the exemplary embodiment of FIG. 6, in contrast to the above-described components, has no component housing 1. In this exemplary embodiment, four LED chips 3 are mounted in an aluminum frame 15 on a heat sink 16, which in turn is disposed on a leadframe 17, here a metal-core board. The heat sink 16 is made of a material that is a good thermal conductor, such as copper, for example, and it serves to carry off the heat developed by the LED chips 3 when operating. Disposed downstream, in the radiation direction of the LED chips 3, from the aluminum frame 15 comprising the LED chips 3 is a separately fabricated lens 9 comprising a first wavelength conversion material 10. As in the exemplary embodiment according to FIG. 1A, the LED chips 3 emit radiation of a first wavelength in the blue region of the spectrum, which is converted by the first wavelength conversion material 10 partially to radiation of a second wavelength in the yellow region of the spectrum, such that the component emits polychromatic mixed radiation having yellow and blue spectral components.

The use of the aluminum frame 15 in the present component is optional. It is suitable for being filled with an encapsulant 8 (not shown) that serves to protect the LED chip 3 and reduces the refractive index mismatch between the LED chip 3 and its environment. In addition, a second wavelength conversion material 12 can be contained in the encapsulant 8, as described with reference to FIGS. 2 and 4.

Furthermore, the inner flanks of the aluminum frame can be configured as reflectors that serve to effect beam shaping.

For electrically contacting the LED chips 3 on their back sides, electrically conductive contact areas 18 are provided on the heat sink 16 and are electrically conductively connected by bonding wires each to a respective electrical connection area 19 on the circuit board 17 laterally of the heat sink 16. On the front side, the LED chips 3 are also each electrically conductively connected by a bonding wire to a corresponding electrical connection area 19.

The electrical connection areas 19 are connected by conductive traces 20 to additional electrical connection areas 21 that establish an electrical connection to pins 22 of an external connector 23. Electrical connector 23 is suitable for being contacted to the outside via a plug-type connector.

For mounting the optoelectronic component, holes 24 for dowel pins are also provided on the circuit board 17. In addition, the circuit board 17 includes varistors 25 to protect the component against electrostatic discharges (ESD protection).

The separate lens 9 further comprises, in the present case, integrated pins 92, which, when the lens 9 is placed on the aluminum frame 15, engage in corresponding holes 26 in the circuit board 17 and snap into them so that the lens 9 is fixed.

The invention is not limited by the description provided with reference to the exemplary embodiments. Rather, the invention encompasses any novel feature and any combination of features, including in particular any combination of features recited in the claims, even if that feature or combination itself is not explicitly mentioned in the claims or exemplary embodiments.

In particular, the invention is not limited to specific wavelength conversion materials, wavelengths, radiation-generating semiconductor bodies or optical elements.

1. An optoelectronic component comprising:
a semiconductor body that emits electromagnetic radiation of a first wavelength when said optoelectronic component is in operation, and
a separate optical element disposed spacedly downstream of said semiconductor body in its radiation direction, said optical element comprising at least one first wavelength conversion material that converts radiation of said first wavelength to radiation of a second wavelength different from said first wavelength.

2. The optoelectronic component as in claim 1, wherein
said first wavelength conversion material includes particles, and
said optoelectronic component comprises a matrix material in which said particles of said first wavelength conversion material are embedded.

3. The optoelectronic component as in claim 1, wherein said first wavelength is in the ultraviolet, blue and/or green region of the spectrum.

4. The optoelectronic component as in claim 1, wherein said component emits polychromatic mixed radiation that includes radiation of said first wavelength and radiation of said second wavelength.

5. The optoelectronic component as in claim 4, wherein said mixed radiation has a color space in the white region of the CIE standard chromaticity diagram.

6. The optoelectronic component as in claim 1, wherein said first wavelength is in the blue region of the spectrum and said second wavelength is in the yellow region of the spectrum.

7. The optoelectronic component as in claim 1, wherein said semiconductor body (3) is provided with an encapsulant (8) that is transparent to the radiation from the component.

8. The optoelectronic component as in claim 7, wherein said encapsulant contains a matrix material that includes a silicone material and/or a refractive-index-matched material.

9. The optoelectronic component as in claim 7, wherein said encapsulant includes at least one second wavelength conversion material different from the first.

10. The optoelectronic component as in claim 9, wherein said second wavelength conversion material converts radiation of said first wavelength to radiation of a third wavelength different from said first and second wavelengths, such that said component emits mixed radiation that includes radiation of said second wavelength, said third wavelength and, where applicable, said first wavelength.

11. The optoelectronic component as in claim 9, wherein said second wavelength conversion material includes particles that are embedded in the said matrix material of said encapsulant.

12. The optoelectronic component as in claim 7, wherein a coupling layer comprising a refractive-index-matched material is disposed between said encapsulant and said separate optical element.

13. The optoelectronic component as in claim 1, wherein applied to said semiconductor body is a wavelength conversion layer that includes at least one third wavelength conversion material different from said first and, where applicable, from said second wavelength conversion material.

14. The optoelectronic component as in claim 13, wherein said third wavelength conversion material converts radiation of said first wavelength to radiation of a fourth wavelength different from said first, said second and, where applicable, said third wavelength, such that said component emits mixed radiation that includes radiation of said third wavelength, said fourth wavelength, where applicable said second wavelength, and where applicable said first wavelength.

15. The optoelectronic component as in claim 13, wherein the thickness of said wavelength conversion layer is constant.

16. The optoelectronic component as in claim 13, wherein
said third wavelength conversion material includes particles, and said wavelength conversion layer comprises a matrix material in which said particles of said third wavelength conversion material are embedded.

17. The optoelectronic component as in claim 9, wherein said first wavelength conversion material, said second wavelength conversion material and, where applicable, said third wavelength conversion material are so arranged that the wavelength to which said first radiation is converted by the particular said wavelength conversion material is shorter, as viewed from said semiconductor body in its radiation direction, than the wavelength to which the preceding wavelength conversion material, with respect to the radiation direction of said semiconductor chip, converts said first radiation.

18. The optoelectronic component as in claim 9, wherein said second wavelength is in the green region of the spectrum and said third or said fourth wavelength is in the red region of the spectrum.

19. The optoelectronic component as in claim 1, wherein said first wavelength conversion material and/or said second wavelength conversion material and/or said third wavelength conversion material comes from the group formed by the following materials: garnets doped with rare earth metals, alkaline earth sulfides doped with rare earth metals, thiogallates doped with rare earth metals, aluminates doped with rare earth metals, orthosilicates doped with rare earth metals, chlorosilicates doped with rare earth metals, alkaline earth silicon nitrides doped with rare earth metals, oxynitrides doped with rare earth metals, and aluminum oxynitrides doped with rare earth metals.

20. The optoelectronic component as in claim 19, wherein YAG:Ce is used as said first wavelength conversion material or said second wavelength conversion material or said third wavelength conversion material.

21. The optoelectronic component as in claim 1, wherein a lens is used as said separate optical element.

22. The optoelectronic component as in claim 21, wherein a convex lens is used as said separate optical element.

23. The optoelectronic component as in claim 2, wherein said matrix material of said optical element comes from the group formed by the following materials: glass, polymethyl methacrylate (PMMA), polycarbonate (PC), cyclic olefins (COC), silicones and polymethyl methylacrylimide (PMMI).

24. The optoelectronic component as in claim 2, wherein said particles of said first wavelength conversion material are substantially uniformly distributed in said matrix material of said optical element.

25. The optoelectronic component as in claim 11, wherein said particles of said second wavelength conversion material are substantially uniformly distributed in said matrix material of said encapsulant.
